(19) United States
(12) Patent Application Publication
(10) Pub. No.: US 2010/0220525 A1
(43) Pub. Date: Sep. 2, 2010

(54) NON-VOLATILE MEMORY DEVICE AND ERASE AND READ METHODS THEREOF

(76) Inventor: Dong Kyu Youn, Ansan-si (KR)

Correspondence Address: F. CHAU & ASSOCIATES, LLC, 130 WOODBURY ROAD, WOODBURY, NY, 11797, US

(21) Appl. No.: 12/702,634

(22) Filed: Feb. 9, 2010

(30) Foreign Application Priority Data
Feb. 27, 2009 (KR) 10-2009-0016872

(51) Int. Cl. G11C 16/04; G11C 16/06

(52) U.S. Cl. 365/185.03; 365/185.29; 365/185.22

(57) ABSTRACT

An erase method of a non-volatile memory device includes first erasing memory cells of a non-volatile memory device with a first erase voltage; in response to a judgment that the erasure of at least one of the memory cells has failed, determining an amount of voltage to add to the first erase voltage, the amount being based on a threshold voltage distribution of the first erased memory cells; and second erasing the memory cells with a second erase voltage, the second erase voltage being higher than the first erase voltage by the determined amount.

### CROSS-REFERENCE TO RELATED APPLICATION

This U.S. non-provisional patent application claims priority under 35 U.S.C. §119 to Korean Patent Application No. 10-2009-0016872 filed on Feb. 27, 2009, the disclosure of which is incorporated by reference herein in its entirety.

### BACKGROUND

1. Technical Field

The present inventive concept relates to a semiconductor memory device, and more particularly, to a non-volatile memory device.

2. Discussion of Related Art

Non-volatile memory devices may include flash memory devices and resistance-variable memory devices, for example. Flash memory devices may be classified into NAND flash memory devices and NOR flash memory devices. NOR flash memory devices include memory cells that are independently connected with bit lines and word lines and have fast random access times. NAND flash memory devices include a plurality of memory cells that are connected in series so that only one contact per string is necessary. Accordingly, NAND flash memory devices have a high degree of integration.

To increase the integration of a flash memory device, developments have been made on a multi-bit cell that is capable of storing a plurality of data bits in one memory cell. Such a memory cell is called a multi-level cell (MLC) or multi-bit cell. A memory cell that is capable of storing one data bit is called a single-level cell (SLC) or single-bit cell. Generally, data bits of a multi-level cell may be programmed to belong to one of two or more threshold voltage distributions. Programming may stress a multi-level cell and cause its threshold voltage distributions to overlap, thus potentially leading to erase and/or read errors. Accordingly, there is a need to reduce cell stress in a nonvolatile memory device.

### SUMMARY

An exemplary embodiment of the inventive concept provides an erase method of a non-volatile memory device, which comprises first erasing memory cells of a non-volatile memory device with a first erase voltage; in response to a judgment that the first erasure of at least one of the memory cells has failed, determining an amount of voltage to add to the first erase voltage, the amount being based on a threshold voltage distribution of the first erased memory cells; and second erasing the memory cells with a second erase voltage, the second erase voltage being higher than the first erase voltage by the determined amount.

The amount to add to the first erase voltage is determined by searching for a maximum upper voltage of the threshold voltage distribution of the first erased memory cells that is less than a verification-read voltage.

The maximum upper voltage is searched for by iteratively performing a verification-read operation.

The erasure of the selected memory cells is terminated by applying the second erase voltage to the memory cells.

The memory cells to be erased are selected.

The memory cells comprise a multi-level cell.

An exemplary embodiment of the inventive concept provides an erase method of a non-volatile memory device, which comprises first erasing memory cells of a non-volatile memory device with a first erase voltage; in response to a judgment that the first erasure of at least one of the memory cells has failed: a) performing a verification operation with a first verification-read voltage; b) obtaining an offset value by using the first verification-read voltage; c) increasing or decreasing the first verification-read voltage by the offset value to generate a new verification-read voltage, based on a result of the verification operation; and d) determining whether the offset value is less than or equal to a reference voltage; and in response to the offset value being less than or equal to the reference voltage, second erasing the memory cells with a second erase voltage obtained by adding the new verification-read voltage to the first erase voltage; otherwise, repeating a-d with each newly generated verification-read voltage as the first verification-read voltage until the offset value is less than or equal to the reference voltage, and then, performing the second erasure of the memory cells.

The verification operation is judged to have passed in response to the first verification-read voltage being higher than a maximum upper voltage of a threshold voltage distribution of the first erased memory cells.

In response to the judgment that the verification operation has passed, the new verification-read voltage is obtained by subtracting the offset value from the first verification-read voltage.

The verification operation is judged to have failed in response to the first verification-read voltage being less than a maximum upper voltage of a threshold voltage distribution of the first erased memory cells.

In response to the judgment that the verification operation has failed, the new verification-read voltage is obtained by adding the offset value to the first verification-read voltage.

The first erasure of at least one of the memory cells is judged to have failed in response to a maximum upper voltage of a threshold voltage distribution of the first erased memory cells being higher than a predetermined verification-read voltage.

The predetermined verification-read voltage is 0V.

The second erase voltage is less than the predetermined verification-read voltage.

The offset value is obtained by dividing the first verification-read voltage by a number more than one.

An exemplary embodiment of the inventive concept provides a read method of a non-volatile memory device, which comprises first reading memory cells of a non-volatile memory device with a first read voltage; in response to a judgment that the first reading of at least one of the memory cells is uncorrectable: a) performing a verification operation with a first read verification voltage; b) obtaining an offset voltage by using the first read verification voltage; c) increasing or decreasing the first read verification voltage by the offset voltage to generate a new read verification voltage, according to a result of the verification operation; and d) determining whether the offset value is less than or equal to a reference voltage; and in response to the offset value being less than or equal to the reference voltage, second reading the memory cells with a second read voltage obtained by adding the new read verification voltage to the first read voltage; otherwise, repeating a-d with each newly generated read verification voltage as the first read verification voltage until the offset value is less than or equal to the reference voltage, and then, performing the second reading of the memory cells.

An error checking and correction (ECC) algorithm determines that the reading of at least one of the memory cells is uncorrectable.

### BRIEF DESCRIPTION OF THE DRAWINGS

The above and other features of the present inventive concept will become more apparent by describing in detail exemplary embodiments thereof with reference to the accompanying drawings.

FIG. 1 is a block diagram showing a non-volatile memory device according to an exemplary embodiment of the inventive concept.

FIG. 2 is a flowchart for describing an erase operation of a non-volatile memory device according to an exemplary embodiment of the inventive concept.

FIGS. 3 to 6 are diagrams showing variations of threshold voltage distributions in an erase operation according to an exemplary embodiment of the inventive concept.

FIG. 7 is a flowchart for describing an erase operation of a non-volatile memory device according to an exemplary embodiment of the inventive concept.

FIG. 8 is a flowchart for describing an erase voltage searching process in FIG. 7.

FIGS. 9 to 12 are diagrams showing threshold voltage distributions in an erase operation according to an exemplary embodiment of the inventive concept.

FIG. 13 is a block diagram showing a computing system including a flash memory device according to an exemplary embodiment of the inventive concept.

FIG. 14 is a block diagram showing a memory-based storage device according to an exemplary embodiment of the inventive concept.

### DETAILED DESCRIPTION OF THE EMBODIMENTS

Exemplary embodiments of the inventive concept will now be described in detail with reference to the accompanying drawings. The inventive concept may, however, be embodied in many different forms and should not be construed as limited to the exemplary embodiments set forth herein. Like reference numerals in the drawings may refer to like elements.

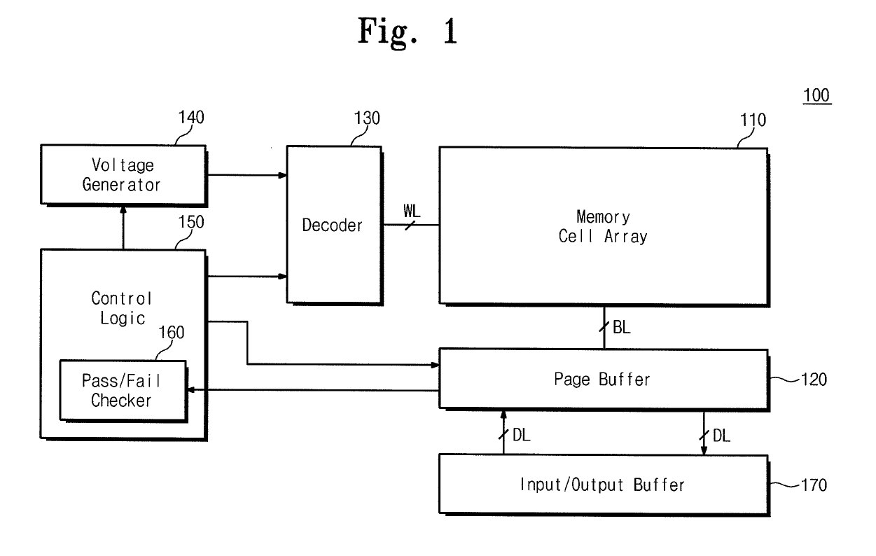

FIG. 1 is a block diagram showing a non-volatile memory device according to an exemplary embodiment of the inventive concept.

Referring to FIG. 1, a non-volatile memory device 100 according to an exemplary embodiment of the inventive concept may be a flash memory device. The non-volatile memory device 100 may be applied to all memory devices which generate interference between memory cells due to integration.

The non-volatile memory device 100 may include a memory cell array 110 which stores M-bit data information (M being an integer of 1 or more). The memory cell array 110 may be divided into a plurality of areas, which include a data area for storing user data and a spare area. But, the areas of the memory cell array 110 are not limited thereto. The areas of the memory cell array 110 may be formed of a plurality of memory blocks, respectively. A memory block structure is well known to one skilled in the art, and a description thereof is thus omitted. For example, an exemplary array structure is disclosed in commonly assigned U.S. Pat. No. 6,285,587, entitled “MEMORY CELL STRING STRUCTURE OF A FLASH MEMORY DEVICE”, the disclosure of which is incorporated by reference herein in its entirety.

The non-volatile memory device 100 may further comprise a page buffer circuit 120, a decoder circuit 130, a voltage generator circuit 140, control logic 150, and an input/output buffer circuit 170.

The page buffer circuit 120 may be configured to read data from or program data in the memory cell array 110 in response to the control of the control logic 150. The decoder circuit 130 may operate in response to the control logic 150. The decoder circuit 130 may be configured to select a memory block of the memory cell array 110 and a word line of the selected memory block. The selected word line may be driven with a word line voltage from the voltage generator circuit 140. The voltage generator circuit 140 may be controlled by the control logic 150 and configured to generate word line voltages (for example, a read voltage, a program voltage, a pass voltage, a local voltage, and a verification voltage) to be supplied to the memory cell array 110.

The control logic 150 may control an overall operation of the non-volatile memory device 100 and include a pass/fail checker 160. The pass/fail checker 160 may be configured to check program/erase pass/fail with respect to data read out by the page buffer circuit 120 in a wired-OR manner or a Y-scan manner. In the wired-OR manner, read data bits may be reflected on a wire at the same time, and the pass/fail checker 160 may judge program/erase pass/fail based on a logic level of the wire. In the Y-scan manner, read data bits may be provided iteratively by a given unit to the pass/fail checker 160 via a column selector which, although not shown, may be included in the input/output buffer circuit 170. The input/output buffer circuit 170 may be configured to transfer data from an external device (for example, a memory controller) to the page buffer circuit 120 or data from the page buffer circuit 120 to the external device.

The non-volatile memory device 100 may be configured to operate in response to a request from an external device such as a memory controller (not shown). Although not shown in the drawings, the memory controller may include a processing unit such as a central processing unit (CPU) or microprocessor, an error checking and correction (ECC) engine, and a buffer memory, for example.

An iterative erase operation may stress non-volatile memory cells. Hot hole injection (HHI) may arise in stressed memory cells. The HHI may make a threshold voltage of a memory cell increase. This may cause a scan fail such that an erased memory cell is judged not to be erased. The stress to memory cells may be reduced by lowering an erase voltage. This may cause incompletely erased memory cells.

The non-volatile memory device 100 according to an exemplary embodiment of the inventive concept may be configured to search for a maximum upper voltage of a threshold voltage distribution after first erasing memory cells and to decide a next erase voltage based on the search result. Memory cells may be completely erased by an erase voltage thus decided. In this process, which will be more fully described hereinafter, an erase voltage is applied to memory cells twice. Accordingly, it is possible to reduce the stress to memory cells to be erased.

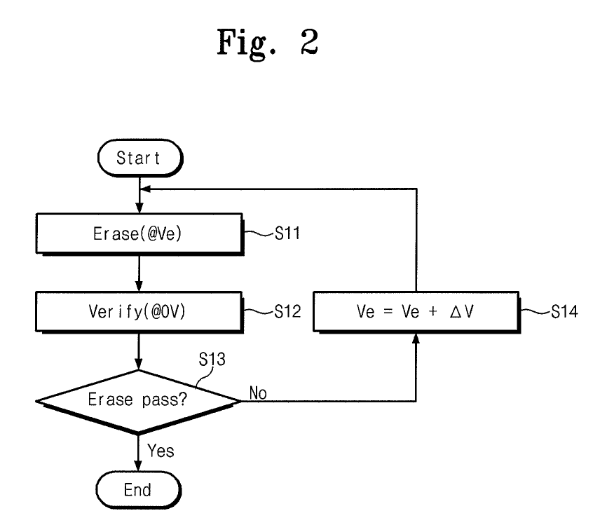

FIG. 2 is a flowchart for describing an erase operation of a non-volatile memory device according to an exemplary embodiment of the inventive concept. An erase operation of a non-volatile memory device according to an exemplary embodiment of the inventive concept will be more fully described with reference to the accompanying drawings.

In step S11, a non-volatile memory device 100 may execute an erase operation based on an initial erase voltage Ve. Here, the initial erase voltage Ve is 18V. The erase voltage Ve may be applied to a bulk (or substrate) on which memory cells are formed. In step S12, the non-volatile memory device 100 may execute a verification-read operation. During the verification-read operation, a verification voltage of 0V may be applied to erased memory cells. In step S13, the non-volatile memory device 100 may judge whether an erase operation has passed or failed. If the erase operation has passed, the erase operation may be ended. If the erase operation has failed, the procedure goes to step S14, in which the erase voltage Ve is increased by an increment ΔV. Afterward, the steps S11 to S14 may be repeated until the erase operation has passed.

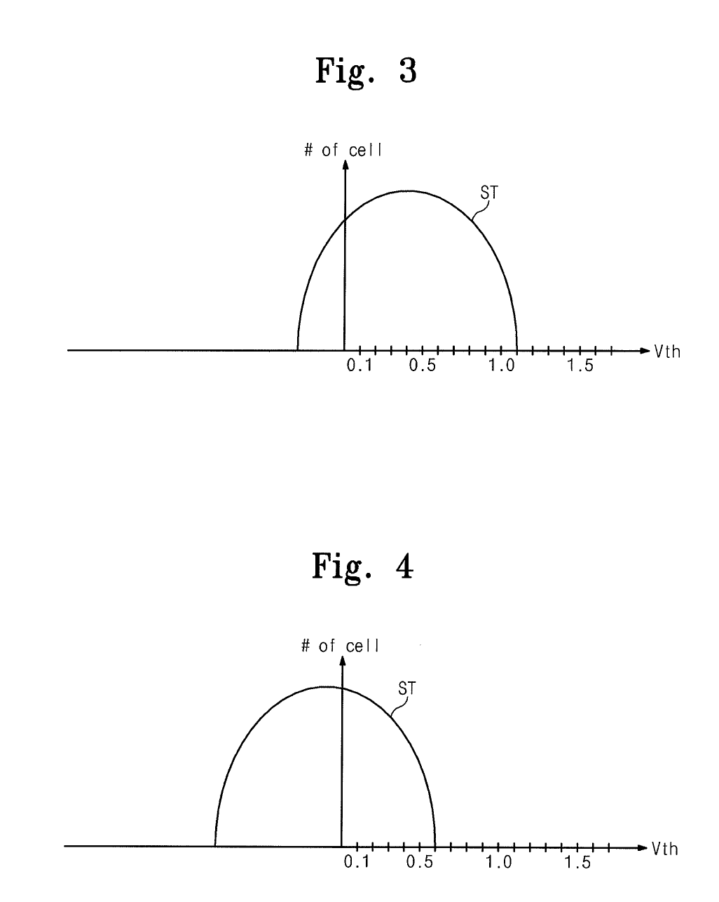

FIGS. 3 to 6 are diagrams showing variations of threshold voltage distributions in an erase operation according to an exemplary embodiment of the inventive concept.

In FIG. 3, there is illustrated a threshold voltage distribution ST of erased memory cells after an erase operation is executed based on an initial erase voltage Ve. As understood from FIG. 3, an erase operation may not be ended even though memory cells are erased in step S11. This is so, because a maximum upper voltage of the threshold voltage distribution ST may be placed over 0V, for example, at about 1.1V higher than a verification-read voltage of 0V. This means that the erase operation is to be performed again with an erase voltage being increased by ΔV. Here, ΔV may be 0.5V.

In FIG. 4, there is illustrated a threshold voltage distribution ST of erased memory cells after an erase operation is executed based on an erase voltage Ve increased by ΔV (0.5V). As illustrated in FIG. 4, a maximum upper voltage of the threshold voltage distribution ST may be placed at about 0.6V higher than the verification-read voltage of 0V. This means that the erase operation is to be performed again with an erase voltage being increased by ΔV.

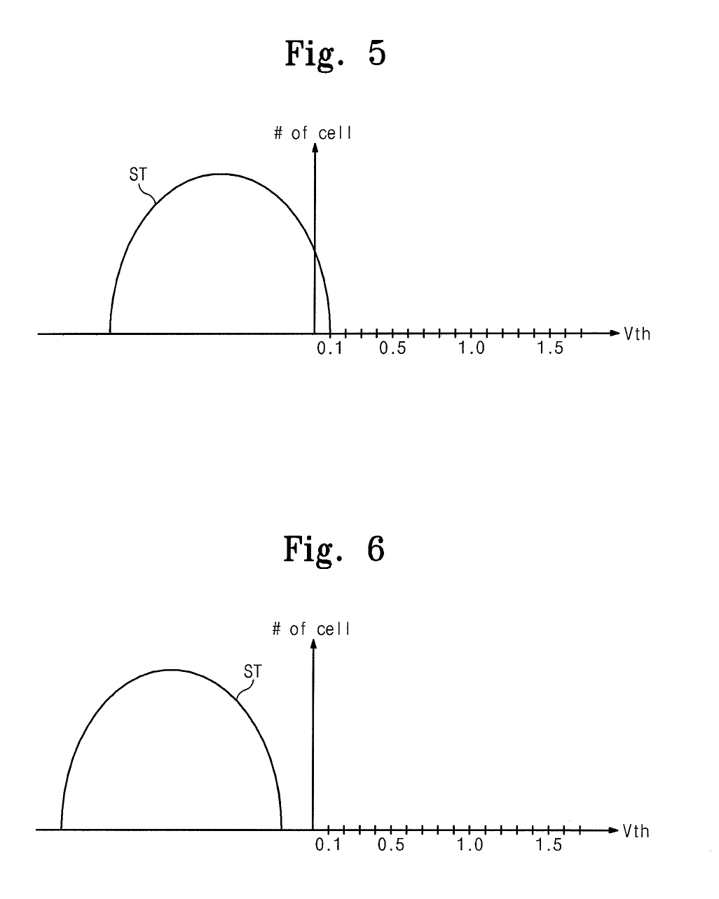

In FIG. 5, there is illustrated a threshold voltage distribution ST of erased memory cells after an erase operation is executed based on an erase voltage Ve increased by 2ΔV (1.0V). As illustrated in FIG. 5, a maximum upper voltage of the threshold voltage distribution ST may be placed at about 0.1V higher than the verification-read voltage of 0V. This means that the erase operation is to be carried out again with an erase voltage being increased by ΔV.

In FIG. 6, there is illustrated a threshold voltage distribution ST of erased memory cells after an erase operation is executed based on an erase voltage Ve increased by 3ΔV (1.5V). As illustrated in FIG. 6, a maximum upper voltage of the threshold voltage distribution ST may be placed below about 0V. This means that the erase operation has passed. Accordingly, the erase operation may be ended.

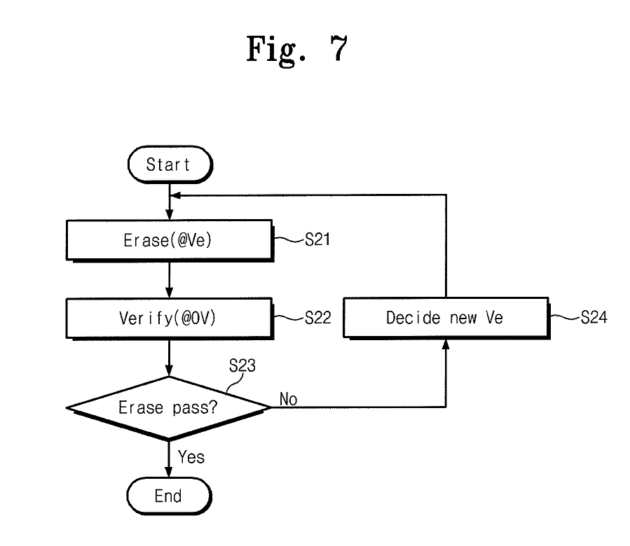

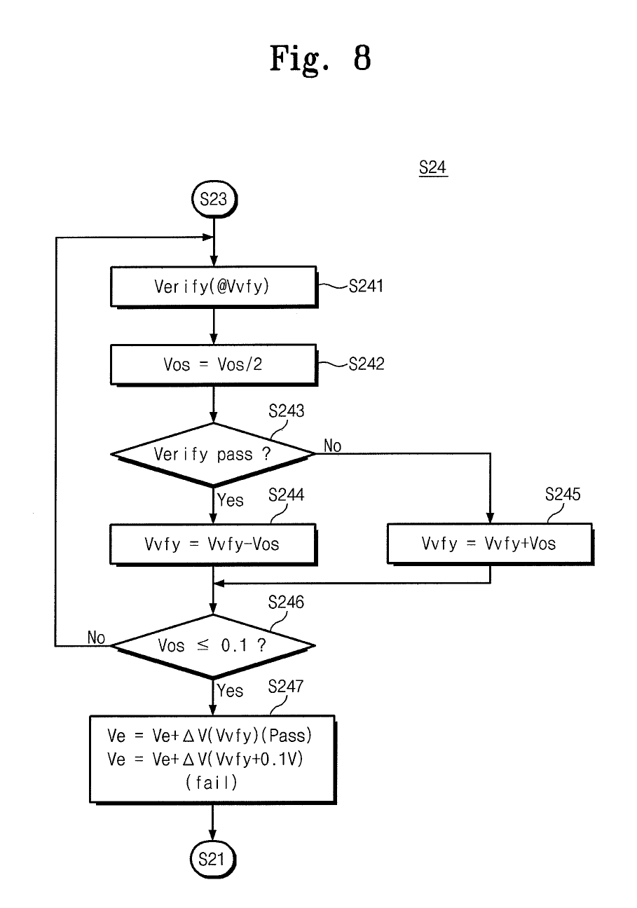

FIG. 7 is a flowchart for describing an erase operation of a non-volatile memory device according to an exemplary embodiment of the inventive concept. FIG. 8 is a flowchart for describing an erase voltage searching process in FIG. 7. Below, an erase operation of a non-volatile memory device according to an exemplary embodiment of the inventive concept will be more fully described with reference to the accompanying drawings.

In step S21, a non-volatile memory device 100 may execute an erase operation based on an erase voltage Ve. In step S22, the non-volatile memory device 100 may execute a verification-read operation. During the verification-read operation, a verification voltage of 0V may be applied to erased memory cells. In step S23, the non-volatile memory device 100 may judge whether an erase operation has passed or failed. If the erase operation is judged to have passed, the erase operation may be ended. If the erase operation is judged to have failed, the procedure goes to step S24, in which there is executed an operation of deciding the erase voltage Ve. In the deciding operation, the erase voltage Ve may be increased not by a fixed increment ΔV (for example, 0.5V), but by a newly decided increment higher or lower than the fixed increment ΔV. This will be more fully described with reference to FIG. 8. After deciding the erase voltage Ve, the procedure goes to step S21.

The erase voltage deciding operation may be performed to decide an increment which to increase an erase voltage. This may be accomplished by searching for a maximum upper voltage of a threshold voltage distribution of erased memory cells in a binary search manner. An erase voltage for next erasing may be decided based on the found maximum upper voltage. This may be executed as follows.

First, in step S241, the non-volatile memory device 100 may execute a first verification-read operation based on a verification-read voltage Vvfy. In an exemplary embodiment, the maximum verification-read voltage Vvfy may be set to about 1.6V. But, the maximum verification-read voltage may not be limited thereto. In step S242, an offset value V_{OS} may be determined by dividing the maximum verification-read voltage Vvfy by 2. The offset value V_{OS} may be used to terminate an operation of searching for a maximum upper voltage of a threshold voltage distribution of erased memory cells. Here, it is possible to change the order of the steps S241 and S242.

In step S243, it may be decided whether the verification-read operation has passed or failed. If the verification-read operation has passed, the procedure goes to step S244, in which the verification-read voltage Vvfy may be decreased by the offset value V_{OS}. If the verification-read operation has failed, the procedure goes to step S245, in which the verification-read voltage Vvfy may be increased by the offset value V_{OS}.

After deciding a new verification-read voltage, in step S246, it may be judged whether the offset value V_{OS} (0.8V) is equal to or less than 0.1V. If the offset value V_{OS} is judged not to be equal to or less than 0.1V, the procedure goes to step S241, in which a second verification-read voltage may be executed based on a verification-read voltage Vvfy decided in step S244/S245. For example, in the event that the verification-read operation is judged to have passed in step S243, the verification-read voltage Vvfy may be set to 0.8V (1.6V−0.8V). In the event that the verification-read operation is judged to have failed in step S243, the verification-read voltage Vvfy may be set to 2.4V (1.6V+0.8V).

In step S246, if the offset value V_{OS} is judged to be equal to or less than 0.1V, the procedure goes to step S247, in which an erase voltage Ve may be set to (Ve+Vvfy) when a last verification-read operation is judged to have passed or to (Ve+Vvfy+0.1V) when a last verification-read operation is judged to have failed. Here, the Vvfy may be an increment ΔV of the erase voltage Ve which is newly determined. Afterwards, the procedure goes to step S21.

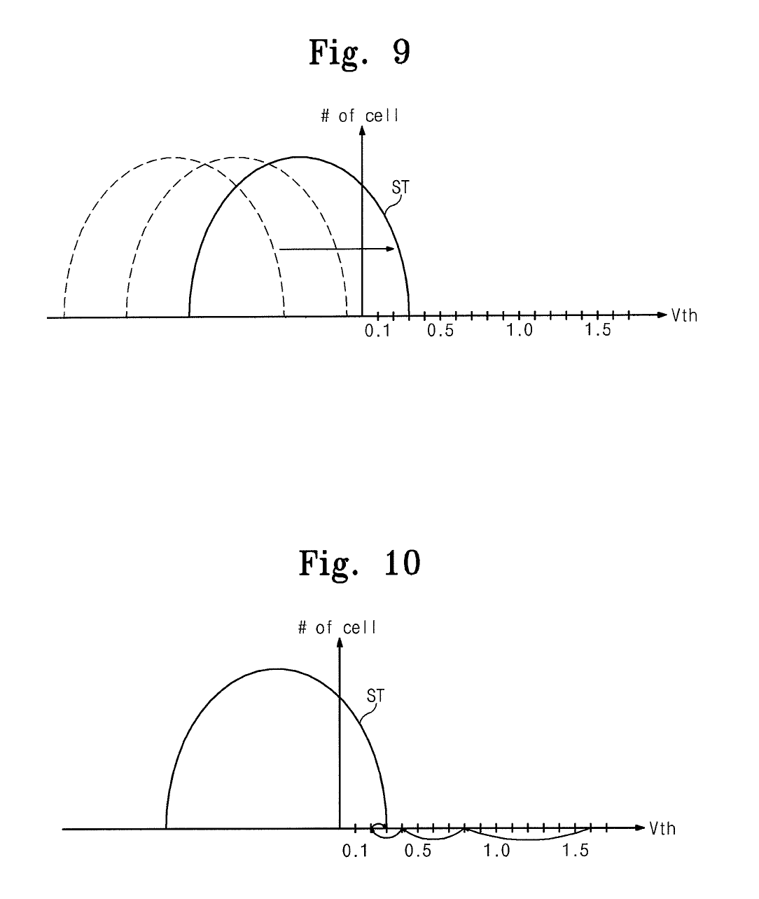

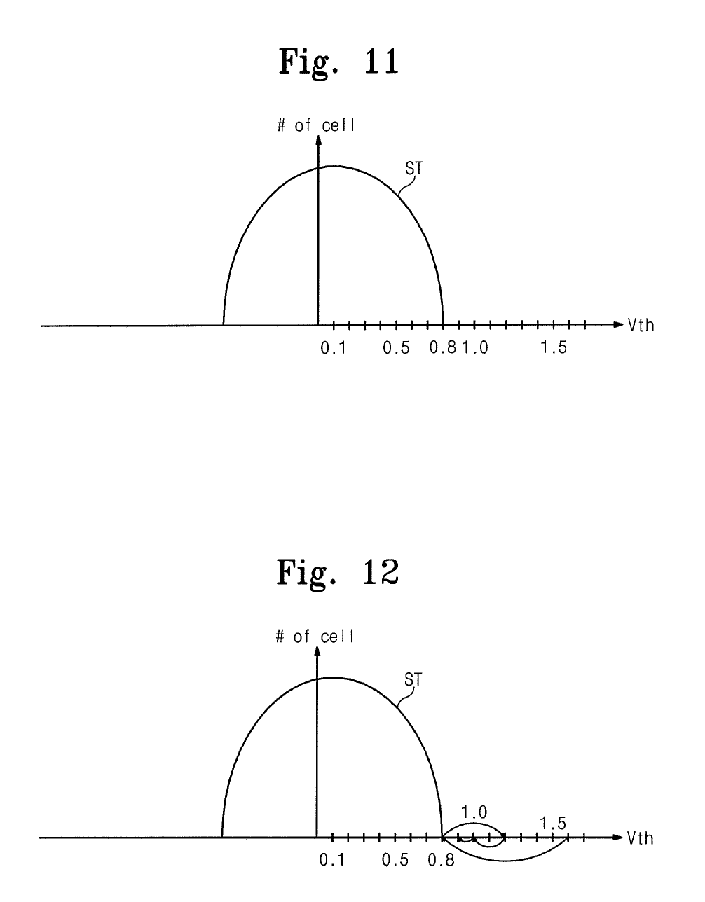

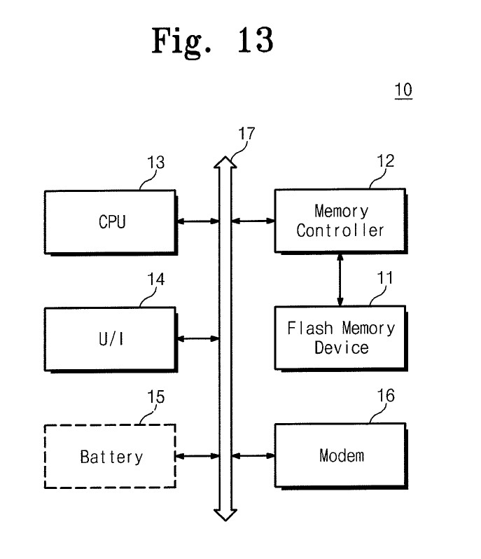

An erase operation according to an exemplary embodiment of the inventive concept will be more fully described with reference to FIGS. 9 to 12.

FIGS. 9 to 12 are diagrams showing threshold voltage distributions in an erase operation according to an exemplary embodiment of the inventive concept. Below, an erase operation according to an exemplary embodiment of the inventive concept will be more fully described with reference to FIGS. 7 to 12.

In FIG. 9, there is illustrated a threshold voltage distribution ST of erased memory cells which experience the above-described HHI.

Referring to FIG. 1 and FIGS. 7 to 9, all memory cells may not be erased completely by the first erase operation executed in step S21. In other words, there exist memory cells whose threshold voltages are higher than 0V, in other words, a verification-read voltage (0V). For this reason, the first erase operation executed in step S21 may be judged to have failed. In this case, in step S24, there may be executed an operation of deciding a new erase voltage.

Referring to FIGS. 7 to 10, in step S241, the non-volatile memory device 100 may execute a first verification-read operation based on a verification-read voltage Vvfy of about 1.6V. In step S242, an offset value V_{OS} may be set to 0.8V which is obtained by dividing an offset value by 2. It is noted that the offset value V_{OS} may be set to the verification-read voltage Vvfy (1.6V) before performing step S242. As described above, the offset value V_{OS} may be used to terminate an operation of searching for a maximum upper voltage of a threshold voltage distribution of erased memory cells.

In step S243, it may be decided whether the verification-read operation has passed or failed. Since the voltage Vvfy of 1.6V is higher than a maximum upper voltage (0.3V) (or, an upper limit voltage), the verification-read operation is judged to have passed. If the verification-read operation is judged to have passed, the verification-read voltage Vvfy may be decreased by the offset value V_{OS}. In other words, a current verification-read voltage Vvfy may be set to 0.8V (1.6V−0.8V). In step S246, it may be judged whether the offset value V_{OS} is less than a reference voltage of 0.1V. Since the offset value V_{OS} (0.8V) is higher than the reference voltage (0.1V), the procedure goes to step S241.

In step S241, the non-volatile memory device 100 may execute a second verification-read operation based on a current verification-read voltage Vvfy of 0.8V. In step S242, the offset value V_{OS} may be set to 0.4V which is obtained by dividing the offset value (0.8V) by 2. In step S243, it may be decided whether the verification-read operation has passed or failed. Since the voltage Vvfy (0.8V) is higher than the maximum upper voltage (0.3V), the verification-read operation is judged to have passed. If the verification-read operation is judged to have passed, the verification-read voltage Vvfy may be decreased by the offset value V_{OS}. In other words, a current verification-read voltage Vvfy may be set to 0.4V (0.8V−0.4V). In step S246, it may be judged whether the offset value V_{OS} is less than a reference voltage of 0.1V. Since the offset value V_{OS} (0.4V) is higher than the reference voltage (0.1V), the procedure goes to step S241.

In step S241, the non-volatile memory device 100 may execute a third verification-read operation based on a verification-read voltage Vvfy of 0.4V. In step S242, the offset value V_{OS} may be set to 0.2V which is obtained by dividing the offset value (0.4V) by 2. In step S243, it may be decided whether the verification-read operation has passed or failed. Since the voltage Vvfy (0.4V) is higher than the maximum upper voltage (0.3V), the verification-read operation is judged to have passed. If the verification-read operation is judged to have passed, the verification-read voltage Vvfy may be decreased by the offset value V_{OS}. In other words, a current verification-read voltage Vvfy may be set to 0.2V (0.4V−0.2V). In step S246, it may be judged whether the offset value V_{OS} is less than a reference voltage of 0.1V. Since the offset value V_{OS} (0.2V) is higher than the reference voltage (0.1V), the procedure goes to step S241.

In step S241, the non-volatile memory device 100 may execute a fourth verification-read operation based on a verification-read voltage Vvfy of 0.2V. In step S242, the offset value V_{OS} may be set to 0.1V which is obtained by dividing the offset value V_{OS} by 2. In step S243, it may be decided whether the verification-read operation has passed or failed. Since the voltage Vvfy (0.2V) is lower than the maximum upper voltage (0.3V), the verification-read operation is judged to have failed. If the verification-read operation is judged to have failed, the verification-read voltage Vvfy may be increased by the offset value V_{OS} (0.1V). In other words, a current verification-read voltage Vvfy may be set to 0.3V (0.2V+0.1V). In step S246, it may be judged whether the offset value V_{OS} is equal to or less than a reference voltage of 0.1V. Since the offset value V_{OS} (0.1V) is equal to the reference voltage (0.1V), the procedure goes to step S247.

The verification-read voltage and the offset voltage may be summarized as follows.

TABLE 1

| | Vvfy | V_{OS} | P/F | Next Vvfy |
|---|---|---|---|---|
| 1^{st} verify read | 1.6 V | 0.8 V | P | 0.8 V (Vvfy − V_{OS}) |
| 2^{nd} verify read | 0.8 V | 0.4 V | P | 0.4 V (Vvfy − V_{OS}) |
| 3^{rd} verify read | 0.4 V | 0.2 V | P | 0.2 V (Vvfy − V_{OS}) |
| 4^{th} verify read | 0.2 V | 0.1 V | F | 0.3 V (Vvfy + V_{OS}) |

As understood from table 1, a maximum upper voltage of a threshold voltage distribution ST may be searched for with the above-described operation. The found maximum upper voltage, in other words, a current verification-read voltage Vvfy may be used as an increment ΔV of an erase voltage Ve. In step S247, there may be decided an erase voltage Ve to be used at a next erase operation, in other words, a second erase operation. For example, an erase voltage Ve may be set to (Ve+Vvfy) when a last verification-read operation is judged to have passed. The erase voltage Ve may be set to (Ve+Vvfy+0.1V) when a last verification-read operation is judged to have failed. As illustrated in table 1, the last verification-read operation is judged to have failed. For this reason, the increment ΔV for the second erase operation may be set to 0.4V (Vvfy+0.1V). Thus, the erase voltage Ve for the second erase operation may be increased by 0.4V. In step S21, the second erase operation may be executed based on the erase voltage thus decided. In step S22, a verification-read operation may be executed based on 0V. The verification-read operation may be judged to have passed in S23. This is because the increment of the erase voltage Ve is set to 0.4V higher than the maximum upper voltage (0.3V). In other words, since threshold voltages of memory cells are shifted in a negative direction by 0.4V, the verification-read operation may be judged to have passed in S23.

In an exemplary embodiment, a given voltage can be added optionally to the increment ΔV (Vvfy/Vvfy+0.1) to minimize the stress to memory cells and to pass the erase operation.

Referring to FIGS. 1, 7, 8 and 11, all memory cells may not be erased completely by the first erase operation executed in step S21. In other words, there exist memory cells whose threshold voltages are higher than 0V, in other words, a verification-read voltage. For this reason, a verification-read operation executed in step S22 may be judged to have failed. In this case, in step S24, there may be executed an operation of deciding a new erase voltage.

Referring to FIGS. 7, 8, 11, and 12, in step S241, the non-volatile memory device 100 may execute a first verification-read operation based on a maximum verification-read voltage Vvfy of 1.6V. In step S242, the offset value V_{OS} may be set to 0.8V which is obtained by dividing an offset value by 2. It is noted that the offset value V_{OS} may be set to the verification-read voltage Vvfy (1.6V) before performing the step S242. In step S243, it may be decided whether the verification-read operation has passed or failed. Since the voltage Vvfy (1.6V) is higher than an upper voltage (0.8V), the verification-read operation is judged to have passed. If the verification-read operation is judged to have passed, the verification-read voltage Vvfy may be decreased by the offset value V_{OS}. In other words, a current verification-read voltage Vvfy may be set to 0.8V (1.6V−0.8V). In step S246, it may be judged whether the offset value V_{OS} is equal to or less than a reference voltage of 0.1V. Since the offset value V_{OS} (0.8V) is higher than the reference voltage (0.1V), the procedure goes to step S241.

In step S241, the non-volatile memory device 100 may execute a second verification-read operation based on a verification-read voltage Vvfy of 0.8V. In step S242, the offset value V_{OS} may be set to 0.4V which is obtained by dividing the offset value (0.8V) by 2. In step S243, it may be decided whether the verification-read operation has passed or failed. Since the voltage Vvfy (0.8V) is equal to the upper voltage (0.8V), the verification-read operation is judged to have failed. If the verification-read operation is judged to have failed, the verification-read voltage Vvfy may be increased by the offset value V_{OS}. In other words, a current verification-read voltage Vvfy may be set to 1.2V (0.8V+0.4V). In step S246, it may be judged whether the offset value V_{OS} is equal to or less than a reference voltage of 0.1V. Since the offset value V_{OS} (0.4V) is higher than the reference voltage (0.1V), the procedure goes to step S241.

In step S241, the non-volatile memory device 100 may execute a third verification-read operation based on a verification-read voltage Vvfy of 1.2V. In step S242, the offset value V_{OS} may be set to 0.2V which is obtained by dividing the offset value (0.4V) by 2. In step S243, it may be decided whether the verification-read operation has passed or failed. Since the voltage Vvfy (1.2V) is higher than the upper voltage (0.8V), the verification-read operation is judged to have passed. If the verification-read operation is judged to have passed, the verification-read voltage Vvfy may be decreased by the offset value V_{OS}. In other words, a current verification-read voltage Vvfy may be set to 1.0V (1.2V−0.2V). In step S246, it may be judged whether the offset value V_{OS} is equal to or less than a reference voltage of 0.1V. Since the offset value V_{OS} (0.2V) is higher than the reference voltage (0.1V), the procedure goes to step S241.

In step S241, the non-volatile memory device 100 may execute a fourth verification-read operation based on a verification-read voltage Vvfy of 1.0V. In step S242, the offset value V_{OS} may be set to 0.1V which is obtained by dividing the offset value (0.2V) by 2. In step S243, it may be decided whether the verification-read operation has passed or failed. Since the voltage Vvfy (1.0V) is higher than the upper limit voltage (0.8V), the verification-read operation is judged to have passed. If the verification-read operation is judged to have passed, the verification-read voltage Vvfy may be decreased by the offset value V_{OS}. In other words, a current verification-read voltage Vvfy may be set to 0.9V (1.0V−0.1V). In step S246, it may be judged whether the offset value V_{OS} is equal to or less than a reference voltage of 0.1V. Since the offset value V_{OS} (0.1V) is equal to the reference voltage (0.1V), the procedure goes to step S247.

The verification-read voltage and the offset voltage may be summarized as follows.

TABLE 2

| | Vvfy | V_{OS} | P/F | Next Vvfy |
|---|---|---|---|---|
| 1^{st} verify read | 1.6 V | 0.8 V | P | 0.8 V (Vvfy − V_{OS}) |
| 2^{nd} verify read | 0.8 V | 0.4 V | F | 1.2 V (Vvfy + V_{OS}) |
| 3^{rd} verify read | 1.2 V | 0.2 V | P | 1.0 V (Vvfy − V_{OS}) |
| 4^{th} verify read | 1.0 V | 0.1 V | P | 0.9 V (Vvfy − V_{OS}) |

As understood from table 2, a maximum upper voltage of a threshold voltage distribution ST may be searched for with the above-described operation. The found maximum upper voltage, in other words, a current verification-read voltage Vvfy may be used as an increment ΔV of an erase voltage Ve. In step S247, there may be decided an erase voltage Ve to be used at a next erase operation, in other words, the second erase operation. For example, an erase voltage Ve may be set to (Ve+Vvfy) when a last verification-read operation is judged to have passed. The erase voltage Ve may be set to (Ve+Vvfy+0.1V) when a last verification-read operation is judged to have failed. As illustrated in table 2, the last verification-read operation is judged to have passed. For this reason, the increment ΔV for the second erase operation may be set to 0.9V. Thus, the erase voltage Ve for the second erase operation may be increased by 0.9V. In step S21, the second erase operation may be executed based on the erase voltage Ve thus decided. In step S22, a verification-read operation may be executed based on 0V. The verification-read operation may be judged to have passed in S23. This is because the increment of the erase voltage Ve is set to 0.9V higher than the maximum upper voltage (0.8V). In other words, since threshold voltages of memory cells are shifted in a negative direction by 0.9V, the verification-read operation may be judged to have passed in S23.

The inventive concept may be applied to search for a new read reference voltage when errors are not recovered by the ECC engine. In other words, exemplary embodiments of the inventive concept may be applied to a read operation since they are applied to a verification-read operation of an erase process.

A read method of a non-volatile memory device according to exemplary an embodiment of the inventive concept comprises a) reading the non-volatile memory device with a read voltage; b) when a read result is uncorrectable by the ECC engine, performing a verification operation based on a maximum read verification voltage; c) increasing or decreasing the maximum read verification voltage by an offset voltage according to the verification result, wherein the offset voltage is obtained by dividing the maximum read verification voltage by 2; and d) performing a verification-read operation based on the thus increased or decreased read verification voltage.

The read method further comprises generating a read voltage which is changed by adding the maximum read verification voltage to the read voltage when the offset voltage is less than a given value. The read method further comprises performing step (a) based on the changed read voltage.

Flash memory devices are a type of nonvolatile memory capable of keeping data stored therein even without power supply. Flash memory devices are used to store code and data in mobile apparatuses such as cellular phones, personal digital assistants (PDA), digital cameras, portable gaming consoles, and MP3 players, for example. Flash memory devices may be also utilized in high-definition TVs, digital versatile disks (DVDs), routers, and global positioning systems (GPSs).

FIG. 13 is a block diagram showing a computing system including a flash memory device according to an exemplary embodiment of the inventive concept. A computing system 10 according to the present inventive concept includes a processing unit 13 such as a microprocessor or a CPU, a user interface 14, a modem 16 such as a baseband chipset, a memory controller 12, and a flash memory device 11. The flash memory device 11 may be configured like that shown FIG. 1. In the flash memory device 11, N-bit data (N is an integer of 1 or more) to be processed by the processing unit 13 are stored through the memory controller 12. If the computing system 10 shown in FIG. 13 is a mobile apparatus, it is further comprised of a battery 15 for supplying power thereto. Although not shown in FIG. 13, the computing system 10 may be further equipped with an application chipset, a camera image processor (e.g., a CMOS image sensor (CIS)), and a mobile dynamic random access memory (DRAM), for example. The memory controller 12 and the flash memory device 11, for example, may be configured to form a solid state drive (SSD) which uses non-volatile memory devices to store data. An exemplary SSD is disclosed in commonly assigned U.S. Patent Application Publication No. 2006/0152981, filed Dec. 19, 2005, the disclosure of which is incorporated by reference herein in its entirety. Alternatively, the memory controller 12 and the flash memory device 11 may be configured to form a memory card which uses non-volatile memory devices to store data.

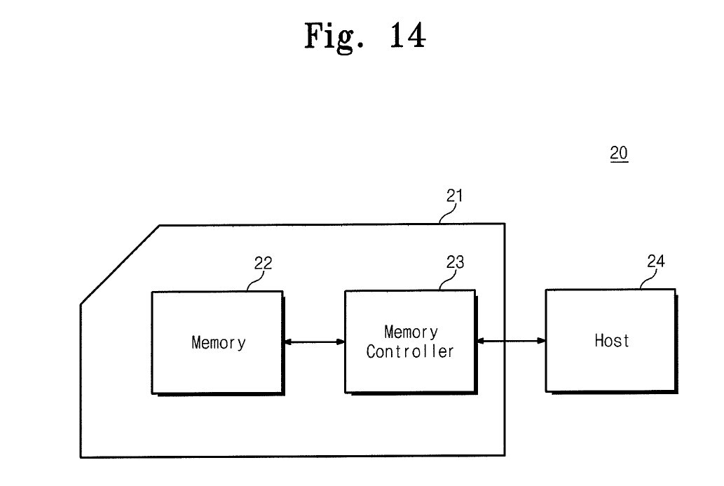

FIG. 14 is a block diagram showing a memory-based storage device according to an exemplary embodiment of the inventive concept.

A memory-based storage device 20 in FIG. 14 may include a card 21 which is formed of a memory 22 and a memory controller 23. For example, the card 21 may be a memory card such as a flash memory card. In other words, the card 21 may be a card which satisfies a standard for use with electronic devices such as digital cameras, and personal computers, for example. It is to be understood that the memory controller 23 controls the memory 22 based on control signals sent from a host 24.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. An erase method of a non-volatile memory device, comprising:
first erasing memory cells of a nonvolatile memory device with a first erase voltage;
in response to a judgment that the first erasure of at least one of the memory cells has failed, determining an amount of voltage to add to the first erase voltage, the amount being based on a threshold voltage distribution of the first erased memory cells; and
second erasing the memory cells with a second erase voltage, the second erase voltage being higher than the first erase voltage by the determined amount.

2. The erase method of claim 1, wherein the amount to add to the first erase voltage is determined by searching for a maximum upper voltage of the threshold voltage distribution of the first erased memory cells that is less than a verification-read voltage.

3. The erase method of claim 2, wherein the maximum upper voltage is searched for by iteratively performing a verification-read operation.

4. The erase method of claim 1, wherein the erasure of the memory cells is terminated by applying the second erase voltage to the memory cells.

5. The erase method of claim 1, wherein the memory cells to be erased are selected.

6. The erase method of claim 1, wherein the memory cells comprise a multi-level cell.

7. An erase method of a non-volatile memory device, comprising:
first erasing memory cells of a non-volatile memory device with a first erase voltage;
in response to a judgment that the first erasure of at least one of the memory cells has failed:
a) performing a verification operation with a first verification-read voltage;
b) obtaining an offset value by using the first verification-read voltage; c) increasing or decreasing the first verification-read voltage by the offset value to generate a new verification-read voltage, based on a result of the verification operation; and
d) determining whether the offset value is less than or equal to a reference voltage; and
in response to the offset value being less than or equal to the reference voltage, second erasing the memory cells with a second erase voltage obtained by adding the new verification-read voltage to the first erase voltage; otherwise, repeating a-d with each newly generated verification-read voltage as the first verification-read voltage until the offset value is less than or equal to the reference voltage, and then, performing the second erasure of the memory cells.

8. The erase method of claim 7, wherein the verification operation is judged to have passed in response to the first verification-read voltage being higher than a maximum upper voltage of a threshold voltage distribution of the first erased memory cells.

9. The erase method of claim 8, wherein in response to the judgment that the verification operation has passed, the new verification-read voltage is obtained by subtracting the offset value from the first verification-read voltage.

10. The erase method of claim 7, wherein the verification operation is judged to have failed in response to the first verification-read voltage being less than a maximum upper voltage of a threshold voltage distribution of the first erased memory cells.

11. The erase method of claim 10, wherein in response to the judgment that the verification operation has failed, the new verification-read voltage is obtained by adding the offset value to the first verification-read voltage.

12. The erase method of claim 7, wherein the first erasure of at least one of the memory cells is judged to have failed in response to a maximum upper voltage of a threshold voltage distribution of the first erased memory cells being higher than a predetermined verification-read voltage.

13. The erase method of claim 12, wherein the predetermined verification-read voltage is 0V.

14. The erase method of claim 12, wherein the second erase voltage is less than the predetermined verification-read voltage.

15. The erase method of claim 7, wherein the offset value is obtained by dividing the first verification-read voltage by a number more than one.

16. A read method of a non-volatile memory device comprising:
first reading memory cells of a non-volatile memory device with a first read voltage;
in response to a judgment that the first reading of at least one of the memory cells is uncorrectable:
a) performing a verification operation with a first read verification voltage;
b) obtaining an offset voltage by using the first read verification voltage;
c) increasing or decreasing the first read verification voltage by the offset voltage to generate a new read verification voltage, according to a result of the verification operation; and
d) determining whether the offset voltage is less than or equal to a reference voltage; and
in response to the offset voltage being less than or equal to the reference voltage, second reading the memory cells with a second read voltage obtained by adding the new read verification voltage to the first read voltage; otherwise, repeating a-d with each newly generated read verification voltage as the first read verification voltage until the offset voltage is less than or equal to the reference voltage, and then, performing the second reading of the memory cells.

17. The read method of claim 16, wherein an error checking and correction (ECC) algorithm determines that the reading of at least one of the memory cells is uncorrectable.
